(19) United States
(12) Patent Application Publication
(10) Pub. No.: US 2006/0006396 A1
(43) Pub. Date: Jan. 12, 2006

(54) Phosphor mixture of organge/red ZnSe0.5S0.5:Cu,Cl and green BaSrGa4S7:Eu for white phosphor-converted led

(76) Inventors: Janet Bee Yin Chua, Perak (MY); Hisham Menkara, Mableton, GA (US); Christopher J. Summers, Dunwoody, GA (US); Brent K. Wagner, Marietta, GA (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/887,598

(22) Filed: Jul. 9, 2004

(51) Int. Cl. H01L 27/15; H01L 29/26; H01L 31/12; H01L 33/00

(52) U.S. Cl. 257/79

(57) ABSTRACT

A device and method for emitting output light utilizes orange/red light emitting ZnSe_{0.5}S_{0.5}:Cu,Cl phosphor material and green light emitting BaSrGa₄S₇:Eu phosphor material to convert some of the original light emitted from a light source of the device to a longer wavelength light to change the optical spectrum of the output light. The device and method can be used to produce white color light using the light source, which may be a blue light emitting diode (LED) die. The orange/red light emitting ZnSe_{0.5}S_{0.5}:Cu,Cl phosphor material and green light emitting BaSrGa₄S₇:Eu phosphor material are included in a wavelength-shifting region optically coupled to the light source.

### BACKGROUND OF THE INVENTION

Conventional light sources, such as incandescent, halogen and fluorescent lamps, have not been significantly improved in the past twenty years. However, light emitting diode (“LEDs”) have been improved to a point with respect to operating efficiency where LEDs are now replacing the conventional light sources in traditional monochrome lighting applications, such as traffic signal lights and automotive taillights. This is due in part to the fact that LEDs have many advantages over conventional light sources. These advantages include longer operating life, lower power consumption, and smaller size.

LEDs are typically monochromatic semiconductor light sources, and are currently available in various colors from UV-blue to green, yellow and red. Due to the narrow-band emission characteristics, monochromatic LEDs cannot be directly used for “white” light applications. Rather, the output light of a monochromatic LED must be mixed with other light of one or more different wavelengths to produce white light. Two common approaches for producing white light using monochromatic LEDs include (1) packaging individual red, green and blue LEDs together so that light emitted from these LEDs are combined to produce white light and (2) introducing fluorescent material into a UV, blue or green LED so that some of the original light emitted by the semiconductor die of the LED is converted into longer wavelength light and combined with the original UV, blue or green light to produce white light.

Between these two approaches for producing white light using monochromatic LEDs, the second approach is generally preferred over the first approach. In contrast to the second approach, the first approach requires a more complex driving circuitry since the red, green and blue LEDs include semiconductor dies that have different operating voltages requirements. In addition to having different operating voltage requirements, the red, green and blue LEDs degrade differently over their operating lifetime, which makes color control over an extended period difficult using the first approach. Moreover, since only a single type of monochromatic LED is needed for the second approach, a more compact device can be made using the second approach that is simpler in construction and lower in manufacturing cost. Furthermore, the second approach may result in broader light emission, which would translate into white output light having higher color-rendering characteristics.

A concern with the second approach for producing white light is that the fluorescent material currently used to convert the original UV, blue or green light results in LEDs having less than desirable luminance efficiency and/or light output stability over time.

In view of this concern, there is a need for an LED and method for emitting white output light using one or more fluorescent phosphor materials with high luminance efficiency and good light output stability.

### SUMMARY OF THE INVENTION

A device and method for emitting output light utilizes orange/red light emitting ZnSe_{0.5}S_{0.5}:Cu,Cl phosphor material and green light emitting BaSrGa₄S₇:Eu phosphor material to convert some of the original light emitted from a light source of the device to a longer wavelength light in order to change the optical spectrum of the output light. The device and method can be used to produce white light using the light source, which may be a blue light emitting diode (LED) die. The orange/red light emitting ZnSe_{0.5}S_{0.5}:Cu,Cl phosphor material and green light emitting BaSrGa₄S₇:Eu phosphor material are included in a wavelength-shifting region optically coupled to the light source.

A device for emitting output light in accordance with an embodiment of the invention includes a light source that emits first light of a first peak wavelength in the blue wavelength range and a wavelength-shifting region optically coupled to the light source to receive the first light. The wavelength-shifting region includes ZnSe_{0.5}S_{0.5}:Cu,Cl phosphor material having a property to convert some of the first light to second light of a second peak wavelength in the orange/red wavelength range. The wavelength-shifting region further includes BaSrGa₄S₇:Eu phosphor material having a property to convert some of the first light to third light of a third peak wavelength in the green wavelength range. The first light, the second light and the third light are components of the output light.

A method for emitting output light in accordance with an embodiment of the invention includes generating first light of a first peak wavelength in the blue wavelength range, receiving the first light, including converting some of the first light to second light of a second peak wavelength in the orange/red wavelength range using ZnSe_{0.5}S_{0.5}:Cu,Cl phosphor material and converting some of the first light to third light of a third peak wavelength in the green wavelength range using BaSrGa₄S₇:Eu phosphor material, and emitting the first light, the second light and the third light as components of the output light.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of a white phosphor-converted LED in accordance with an embodiment of the invention.

FIGS. 2A, 2B and 2C are diagrams of white phosphor-converted LEDs with alternative lamp configurations in accordance with an embodiment of the invention.

FIGS. 3A, 3B, 3C and 3D are diagrams of white phosphor-converted LEDs with a leadframe having a reflector cup in accordance with an alternative embodiment of the invention.

FIG. 4 shows the optical spectrum of a white phosphor-converted LED in accordance with an embodiment of the invention.

FIG. 5 is a flow diagram of a method for emitting output light in accordance with an embodiment of the invention.

### DETAILED DESCRIPTION

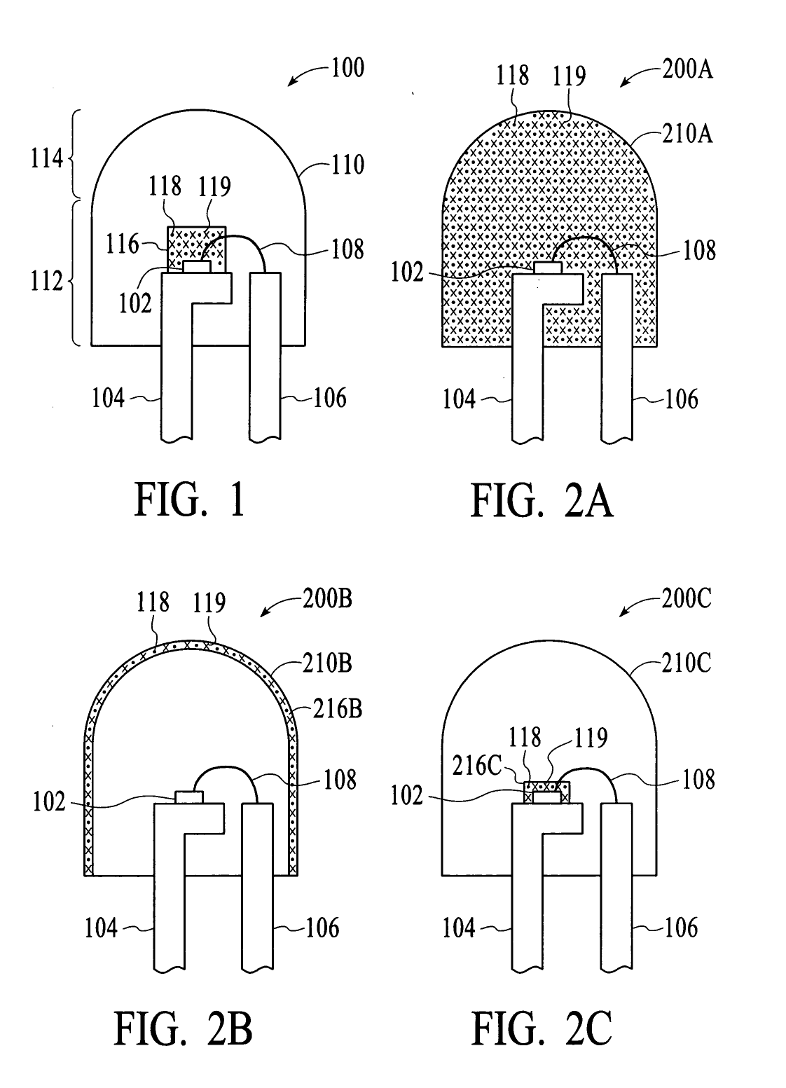

With reference to FIG. 1, a white phosphor-converted light emitting diode (LED) 100 in accordance with an embodiment of the invention is shown. The LED 100 is designed to produce “white” color output light with high luminance efficiency and good light output stability. The white output light is produced by converting some of the original light generated by the LED 100 into longer wavelength light using orange/red light emitting ZnSe_{0.5}S_{0.5}:Cu,Cl phosphor material and green emitting BaSrGa₄S₇:Eu phosphor material.

As shown in FIG. 1, the white phosphor-converted LED 100 is a leadframe-mounted LED. The LED 100 includes an LED die 102, leadframes 104 and 106, a wire 108 and a lamp 110. The LED die 102 is a semiconductor chip that generates light of a particular peak wavelength. In an exemplary embodiment, the LED die 102 is designed to generate light having a peak wavelength in the blue wavelength range of the visible spectrum, which is approximately 420 nm to 490 nm. The LED die 102 is situated on the leadframe 104 and is electrically connected to the other leadframe 106 via the wire 108. The leadframes 104 and 106 provide the electrical power needed to drive the LED die 102. The LED die 102 is encapsulated in the lamp 110, which is a medium for the propagation of light from the LED die 102. The lamp 110 includes a main section 112 and an output section 114. In this embodiment, the output section 114 of the lamp 110 is dome-shaped to function as a lens. Thus, the light emitted from the LED 100 as output light is focused by the dome-shaped output section 114 of the lamp 110. However, in other embodiments, the output section 114 of the lamp 100 may be horizontally planar.

The lamp 110 of the white phosphor-converted LED 100 is made of a transparent substance, which can be any transparent material such as clear epoxy, so that light from the LED die 102 can travel through the lamp and be emitted out of the output section 114 of the lamp. In this embodiment, the lamp 110 includes a wavelength-shifting region 116, which is also a medium for propagating light, made of a mixture of the transparent substance and two types of fluorescent phosphor materials, orange/red light emitting ZnSe_{0.5}S_{0.5}:Cu,Cl phosphor 118 and green light emitting BaSrGa₄S₇:Eu phosphor 119. The ZnSe_{0.5}S_{0.5}:Cu,Cl phosphor material 118 and the BaSrGa₄S₇:Eu phosphor material 119 are used to convert some of the original light emitted by the LED die 102 to lower energy (longer wavelength) light. The ZnSe_{0.5}S_{0.5}:Cu,Cl phosphor material 118 absorbs some of the original light of a first peak wavelength from the LED die 102, which excites the atoms of the ZnSe_{0.5}S_{0.5}:Cu,Cl phosphor material, and emits longer wavelength light of a second peak wavelength in the orange/red wavelength range of the visible spectrum, which is approximately 610 nm to 650 nm. Similarly, the BaSrGa₄S₇:Eu phosphor material 119 absorbs some of the original light from the LED die 102, which excites the atoms of the BaSrGa₄S₇:Eu phosphor material, and emits longer wavelength light of a third peak wavelength in the green wavelength range of the visible spectrum, which is approximately 520 nm to 540 nm. The second and third peak wavelengths of the converted light are partly defined by the peak wavelength of the original light, and the ZnSe_{0.5}S_{0.5}:Cu,Cl phosphor material 118 and the BaSrGa₄S₇:Eu phosphor material 119. The unabsorbed original light from the LED die 102 and the converted light are combined to produce “white” color light, which is emitted from the light output section 114 of the lamp 110 as output light of the LED 100.

The ZnSe_{0.5}S_{0.5}:Cu,Cl phosphor 118 can be synthesized by various techniques. One technique involves dry-milling a 1:1 molar ratio of undoped ZnSe and ZnS materials into fine powders or crystals, which may be less than 5 μm. A small amount of CuCl₂ dopants is then added to de-ionized water or a solution from the alcohol family, such as methanol, and ball-milled with the undoped ZnSe_{0.5}S_{0.5} powders. The amount of CuCl₂ dopants added to the solution can be anywhere between a minimal amount (few parts per million) to approximately four percent of the total weight of ZnSe_{0.5}S_{0.5} material and CuCl₂ dopants. The doped material is then oven-dried at around one hundred degrees Celsius (100° C.), and the resulting cake is dry-milled again to produce small particles. The milled material is loaded into a crucible, such as a quartz crucible, and sintered in an inert atmosphere at around one thousand degrees Celsius (1,000° C.) for one to two hours. The sintered materials can then be sieved, if necessary, to produce ZnSe_{0.5}S_{0.5}:Cu,Cl phosphor powders with desired particle size distribution, which may be in the micron range.

The BaSrGa₄S₇:Eu phosphor 119 can also be synthesized by various techniques. One technique involves using BaS, SrS and Ga₂S₃ as precursors. The precursors are ball-milled in de-ionized water or a solution from the alcohol family, such as methanol, along with a small amount of Eu dopant, fluxes (Cl and F) and excess sulfur. The amount of Eu dopant added to the solution can be anywhere between a minimal amount to approximately ten percent of the total weight of all ingredients. The doped material is then dried and subsequently milled to produce fine particles. The milled particles are then loaded into a crucible, such as a quartz crucible, and sintered in an inert atmosphere at around eight hundred degrees Celsius (800° C.) for one to two hours. The sintered materials can then be sieved, if necessary, to produce BaSrGa₄S₇:Eu phosphor powders with desired particle size distribution, which may be in the micron range.

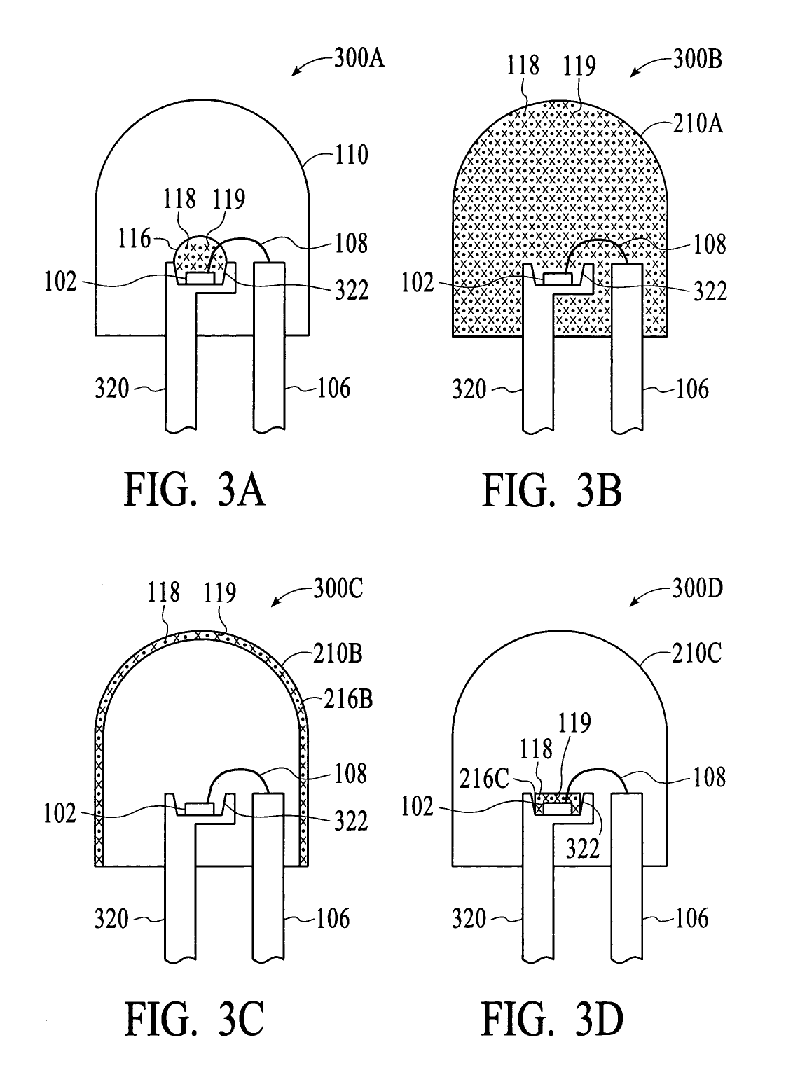

Following the completion of the ZnSe_{0.5}S_{0.5}:Cu,Cl and BaSrGa₄S₇:Eu synthesis processes, the ZnSe_{0.5}S_{0.5}:Cu,Cl and BaSrGa₄S₇:Eu phosphor powders can be mixed with the same transparent substance of the lamp 110, e.g., epoxy, and deposited around the LED die 102 to form the wavelength-shifting region 116 of the lamp. The ratio between the two different types of phosphor powders can be adjusted to produce different color characteristics for the white phosphor-converted LED 100. As an example, the ratio between the ZnSe_{0.5}S_{0.5}:Cu,Cl phosphor powers and the BaSrGa₄S₇:Eu phosphor powders may be [1:7], respectively. The remaining part of the lamp 110 can be formed by depositing the transparent substance without the ZnSe_{0.5}S_{0.5}:Cu,Cl and BaSrGa₄S₇:Eu phosphor powders to produce the LED 100. Although the wavelength-shifting region 116 of the lamp 110 is shown in FIG. 1 as being rectangular in shape, the wavelength-shifting region may be configured in other shapes, such as a hemisphere, as shown in FIG. 3A. Furthermore, in other embodiments, the wavelength-shifting region 116 may not be physically coupled to the LED die 102. Thus, in these embodiments, the wavelength-shifting region 116 may be positioned elsewhere within the lamp 110.

In FIGS. 2A, 2B and 2C, white phosphor-converted LEDs 200A, 200B and 200C with alternative lamp configurations in accordance with an embodiment of the invention are shown. The white phosphor-converted LED 200A of FIG. 2A includes a lamp 210A in which the entire lamp is a wavelength-shifting region. Thus, in this configuration, the entire lamp 210A is made of the mixture of the transparent substance, and the ZnSe_{0.5}S_{0.5}:Cu,Cl and BaSrGa₄S₇:Eu phosphor materials 118 and 119. The white phosphor-converted LED 200B of FIG. 2B includes a lamp 210B in which a wavelength-shifting region 216B is located at the outer surface of the lamp. Thus, in this configuration, the region of the lamp 210B without the ZnSe_{0.5}S_{0.5}:Cu,Cl and BaSrGa₄S₇:Eu phosphor materials 118 and 119 is first formed over the LED die 102 and then the mixture of the transparent substance and the phosphor materials is deposited over this region to form the wavelength-shifting region 216B of the lamp. The white phosphor-converted LED 200C of FIG. 2C includes a lamp 210C in which a wavelength-shifting region 216C is a thin layer of the mixture of the transparent substance and the ZnSe_{0.5}S_{0.5}:Cu,Cl and BaSrGa₄S₇:Eu phosphor materials 118 and 119 coated over the LED die 102. Thus, in this configuration, the LED die 102 is first coated or covered with the mixture of the transparent substance and the ZnSe_{0.5}S_{0.5}:Cu,Cl and BaSrGa₄S₇:Eu phosphor materials 118 and 119 to form the wavelength-shifting region 216C and then the remaining part of the lamp 210C can be formed by depositing the transparent substance without the phosphor materials over the wavelength-shifting region. As an example, the thickness of the wavelength-shifting region 216C of the LED 200C can be between ten (10) and sixty (60) microns, depending on the color of the light generated by the LED die 102.

In an alternative embodiment, the leadframe of a white phosphor-converted LED on which the LED die is positioned may include a reflector cup, as illustrated in FIGS. 3A, 3B, 3C and 3D. FIGS. 3A-3D show white phosphor-converted LEDs 300A, 300B, 300C and 300D with different lamp configurations that include a leadframe 320 having a reflector cup 322. The reflector cup 322 provides a depressed region for the LED die 102 to be positioned so that some of the light generated by the LED die is reflected away from the leadframe 320 to be emitted from the respective LED as useful output light.

The different lamp configurations described above can be applied other types of LEDs, such as surface-mounted LEDs, to produce other types of white phosphor-converted LEDs with the ZnSe_{0.5}S_{0.5}:Cu,Cl and BaSrGa₄S₇:Eu phosphor materials 118 and 119 in accordance with the invention. In addition, these different lamp configurations may be applied to other types of light emitting devices, such as semiconductor lasing devices, to produce other types of light emitting device in accordance with the invention.

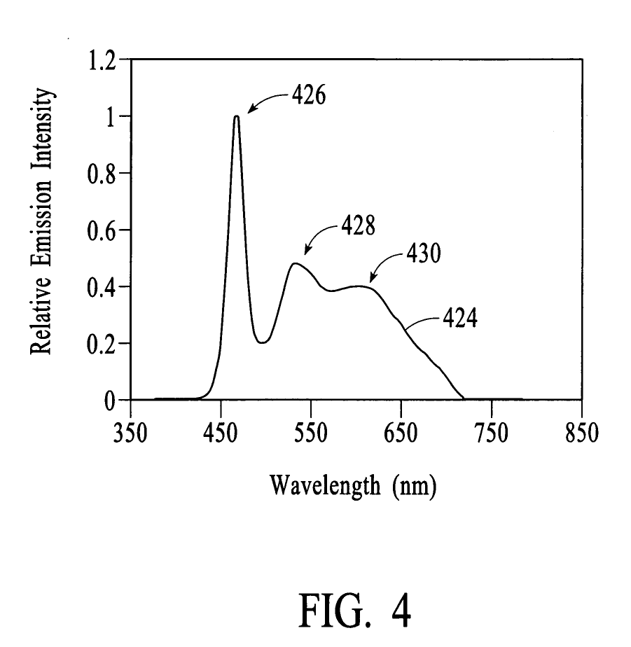

Turning now to FIG. 4, the optical spectrum 424 of a phosphor-converted LED with a blue (440-480 nm) LED die in accordance with an embodiment of the invention is shown. The wavelength-shifting region for this LED was formed with sixty-five percent (65%) of ZnSe_{0.5}S_{0.5}:Cu,Cl and BaSrGa₄S₇:Eu phosphors relative to epoxy. The percentage amount or loading content of ZnSe_{0.5}S_{0.5}:Cu,Cl and BaSrGa₄S₇:Eu phosphors included in the wavelength-shifting region of the LED can be varied according to phosphor efficiency. As the phosphor efficiency is increased, e.g., by changing the amount of dopant(s), the loading content of the ZnSe_{0.5}S_{0.5}:Cu,Cl and BaSrGa₄S₇:Eu phosphors may be reduced. The optical spectrum 424 includes a first peak wavelength 426 at around 460 nm, which corresponds to the peak wavelength of the light emitted from the blue LED die. The optical spectrum 424 also includes a second peak wavelength 428 at around 540 nm, which is the peak wavelength of the light converted by the BaSrGa₄S₇:Eu phosphor in the wavelength-shifting region of the LED, and a third peak wavelength 430 at around 625 nm, which is the peak wavelength of the light converted by the ZnSe_{0.5}S_{0.5}:Cu,Cl phosphor in the wavelength-shifting regions of the LED.

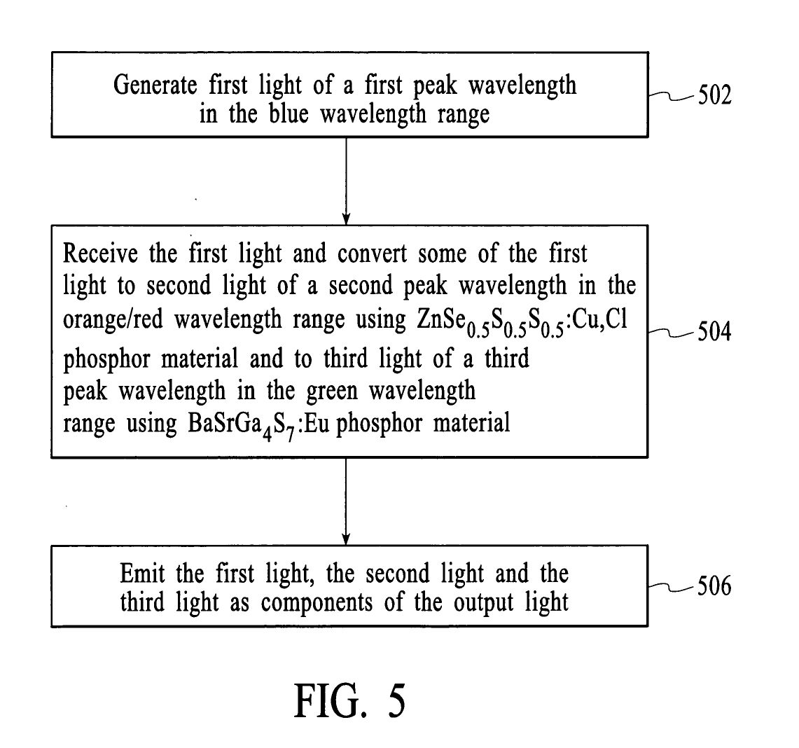

A method for producing output light in accordance with an embodiment of the invention is described with reference to FIG. 5. At block 502, first light of a first peak wavelength in the blue wavelength range is generated. The first light may be generated by an LED die. Next, at block 504, the first light is received and some of the first light is converted to second light of a second peak wavelength in the orange/red wavelength range using the ZnSe_{0.5}S_{0.5}:Cu,Cl phosphor material. Furthermore, at block 504, some of the first light is converted to third light of a third peak wavelength in the green wavelength range using BaSrGa₄S₇:Eu phosphor material. Next, at block 506, the first light, the second light and the third light are emitted as components of the output light.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A device for emitting output light, said device comprising:
a semiconductor light emitting diode that emits first light of a first peak wavelength in a blue wavelength range; and
a wavelength-shifting region optically coupled to said light source to receive said first light, said wavelength-shifting region including ZnSe_{0.5}S_{0.5}:Cu,Cl phosphor material having a property to convert some of said first light to second light of a second peak wavelength in an orange/red wavelength range, said wavelength-shifting region further including BaSrGa₄S₇:Eu phosphor material having a property to convert some of said first light to third light of a third peak wavelength in a green wavelength range, said first light, said second light and said third light being components of said output light.

2. The device of claim 1 wherein said wavelength-shifting region is a part of a lamp coupled to said semiconductor light emitting diode.

3. The device of claim 2 wherein said wavelength-shifting region is located at an outer surface of said lamp.

4. The device of claim 1 wherein said wavelength-shifting region is a lamp coupled to said semiconductor light emitting diode.

5. The device of claim 1 wherein said wavelength-shifting region is a layer of mixture coated over said semiconductor light emitting diode, said mixture including said ZnSe_{0.5}S_{0.5}:Cu,Cl phosphor material and said BaSrGa₄S₇:Eu phosphor material.

6. The device of claim 1 further comprising a reflector cup on which said semiconductor light emitting diode is positioned.

7. A method for emitting output light from a light emitting diode, said method comprising:
generating first light of a first peak wavelength in a blue wavelength range;
receiving said first light, including converting some of said first light to second light of a second peak wavelength in an orange/red wavelength range using ZnSe_{0.5}S_{0.5}:Cu,Cl phosphor material and converting some of said first light to third light of a third peak wavelength in a green wavelength range using BaSrGa₄S₇:Eu phosphor material; and
emitting said first light, said second light and said third light as components of said output light.

8. The method of claim 15 wherein said receiving includes receiving said first light of said first peak wavelength at a wavelength-shifting region of a light emitting device.

9. The method of claim 17 wherein said wavelength-shifting region is part of a lamp of said light emitting device.

10. The method of claim 17 wherein said wavelength-shifting region is a lamp of said light emitting device.

11. The method of claim 17 wherein said wavelength-shifting region is a layer of mixture coated over said light emitting diode, said mixture including said ZnSe_{0.5}S_{0.5}:Cu,Cl phosphor material and said BaSrGa₄S₇:Eu phosphor material.
